(19) United States
(12) Patent Application Publication
(10) Pub. No.: US 2016/0066453 A1
(43) Pub. Date: Mar. 3, 2016

(54) ELECTRONIC DEVICE CASE HAVING A KICKSTAND WITH A REMOVABLE CHARGER CABLE

(71) Applicant: DAYMEN CANADA ACQUISITION ULC, Vancouver (CA)

(72) Inventors: Luis Quehl, San Anselmo, CA (US); Philip de los Reyes, Berkeley, CA (US); Courtney Spens, Sebastopol, CA (US); Kevin Crandall, Santa Rosa, CA (US)

(21) Appl. No.: 14/469,652

(22) Filed: Aug. 27, 2014

(51) Int. Cl. H05K 5/02; A45C 13/00; H05K 5/03; A45C 11/00

(52) U.S. Cl. CPC H05K 5/0234; A45C 11/00; A45C 13/002; A45C 13/001; A45C 13/005; H05K 5/03; H05K 5/0226; H05K 5/0247; A45C 2011/002; A45C 2011/003; A45C 2011/001

(57) ABSTRACT

An electronic device case includes a panel including a front surface, a back surface, and a recess. The case further includes a kickstand with a first end hingedly connected to the panel such that the kickstand in a closed configuration is at least partially disposed in the recess of the panel and an open configuration a second end of the kickstand is spaced from the panel. A storage area is disposed in the recess. The storage area is configured to hold a charge or data cable for the electronic device and is configured such that the charge or data cable may be disposed therein with kickstand in the closed configuration and the open configuration.

### FIELD OF THE INVENTION

The invention is related to a holder or case for portable electronic devices, and in particular, to a case having a kickstand with a removable charger cable.

### BACKGROUND OF THE INVENTION

There are a wide variety of portable electronic devices such as personal digital assistants (PDSs), smartphones, mobile phones, satellite phones, music players, MP3 players, media players, digital cameras, tablet computers, and portable game consoles. These portable electronic devices typically use a battery as their primary power source. However, these batteries must be recharged at various intervals, depending on the device, battery age, usage, and other factors affecting battery life. Thus, users often carry cables or other devices for charging the portable device battery. However, users do not wish to carry cables with them all the time, and users often forget charging cables when travelling.

Many users also use a holder or case for these portable electronic devices. These cases protect the portable electronic device from damage, and may include other features to assist in viewing the portable electronic device. Thus, it would be desirable for the portable electronic device case to incorporate a charging cable. Further, it would be desirable for the user to be able to use the portable electronic device while it is being charged.

### BRIEF SUMMARY OF THE INVENTION

Embodiments hereof relate to a case for portable electronic devices. In particular, in an embodiment, an electronic device case includes a panel including a front surface, a back surface, and a recess. The case further includes a kickstand with a first end hingedly connected to the panel such that the kickstand in a closed configuration is at least partially disposed in the recess of the panel and an open configuration a second end of the kickstand is spaced from the panel. A storage area is disposed in the recess. The storage area is configured to hold a charge or data cable for the electronic device and is configured such that the charge or data cable may be disposed therein with kickstand in the closed configuration and the open configuration.

In other embodiments, an electronic device case includes a panel including a front surface and a back surface, and a kickstand. The kickstand includes a support tube with a first end hingedly connected to the panel such that the support tube in a closed configuration is at least partially disposed in an opening or recess of the panel and in an open configuration a second end of the support tube is spaced from the panel. The support tube includes a bore disposed longitudinally, wherein the bore is configured to hold a charge or data cable for the electronic device.

### BRIEF DESCRIPTION OF DRAWINGS

The foregoing and other features and advantages of the invention will be apparent from the following description of the invention as illustrated in the accompanying drawings. The accompanying drawings, which are incorporated herein and form a part of the specification, further serve to explain the principles of the invention and to enable a person skilled in the pertinent art to make and use the invention. The drawings are not to scale.

FIG. 1 is a schematic illustration of a rear view of an embodiment of an electronic device case according to an embodiment hereof, showing a kickstand of the case in a closed configuration.

FIG. 2 is a schematic illustration of a front view of electronic device case of FIG. 1.

FIG. 3 is a schematic illustration of a side view of the electronic device case of FIG. 1 with an electronic device in the case.

FIG. 4 is a schematic illustration of the back of the electronic device case of FIG. 1 with the kickstand open and the charge cable in the stored position.

FIG. 5 is a close-up schematic illustration of a portion of the back of electronic device of FIG. 1 with the kickstand open and the charge cable in the stored position.

FIG. 5A is a schematic cross-sectional illustration taken through the kickstand of FIG. 5.

FIG. 6 is a schematic illustration of the electronic device case of FIG. 1 with the kickstand in the open configuration for portrait viewing of the electronic device.

FIG. 7 is another view of the electronic device case of FIG. 1 with the kickstand in the open configuration for portrait viewing of the electronic device.

FIG. 8 is a schematic illustration of the electronic device case of FIG. 1 with the kickstand open for landscape viewing of the portable electronic device and the charge cable removed from the case.

FIG. 9 is a schematic illustration of the electronic device case of FIG. 1 with the charging cable removed from the kickstand and connected to the electronic device for connection to a charging device, and the kickstand in the open configuration and the case oriented for landscape viewing of the electronic device.

FIG. 10 is a schematic illustration of the rear panel of an electronic device case according to another embodiment hereof, showing a kickstand of the case in a closed configuration.

FIG. 11 is a schematic illustration of the front of electronic device case of FIG. 10 with the kickstand in to the closed configuration.

FIG. 12 is a schematic illustration of the electronic device case of FIG. 10 with the kickstand in the open configuration for portrait viewing of the electronic device.

FIG. 13 is a schematic illustration of the electronic device case of FIG. 10 with the kickstand open for landscape viewing of the portable electronic device.

FIG. 14 is a schematic illustration of the components of the kickstand.

FIG. 15 is a schematic illustration of the kickstand with the charging cable removed.

FIG. 16 is a schematic illustration of the charging cable removed from the kickstand.

FIG. 17 is a schematic illustration of another view of the charging cable removed from the kickstand.

FIG. 18 is a schematic illustration of a side view of the charging cable removed from the kickstand.

FIG. 19 is a schematic illustration of the electronic device case of FIG. 10 with the charging cable removed and the kickstand in the open configuration and the case oriented for portrait viewing of the electronic device.

FIG. 20 is a schematic illustration of the electronic device case of FIG. 10 with the charging cable removed and the kickstand in the open configuration and the case oriented for landscape viewing of the electronic device.

FIG. 21 is a schematic illustration of the electronic device case of FIG. 10 with the charging cable removed from the kickstand and connected to the electronic device for connection to a charging device, and the kickstand in the open configuration and the case oriented for landscape viewing of the electronic device.

### DETAILED DESCRIPTION OF THE INVENTION

Specific embodiments of the present invention are now described with reference to the figures, wherein like reference numbers indicate identical or functionally similar elements. The following detailed description is merely exemplary in nature and is not intended to limit the invention or the application and uses of the invention. There is no intention to be bound by any expressed or implied theory presented in the preceding technical field, background, brief summary or the following detailed description.

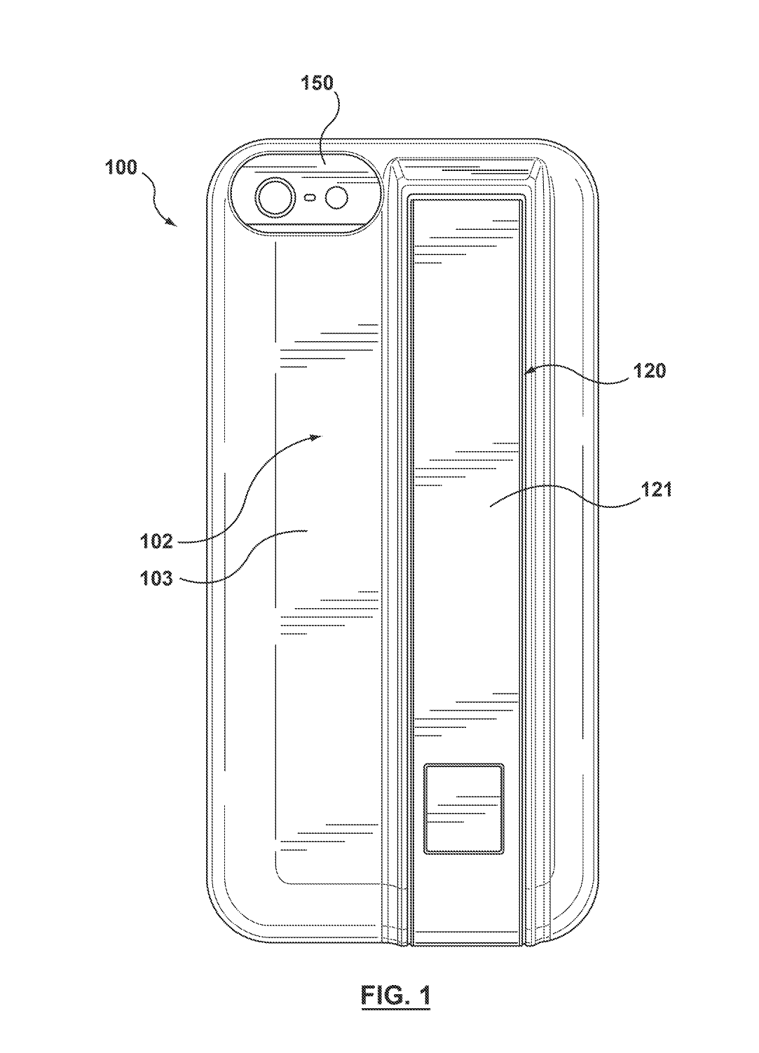

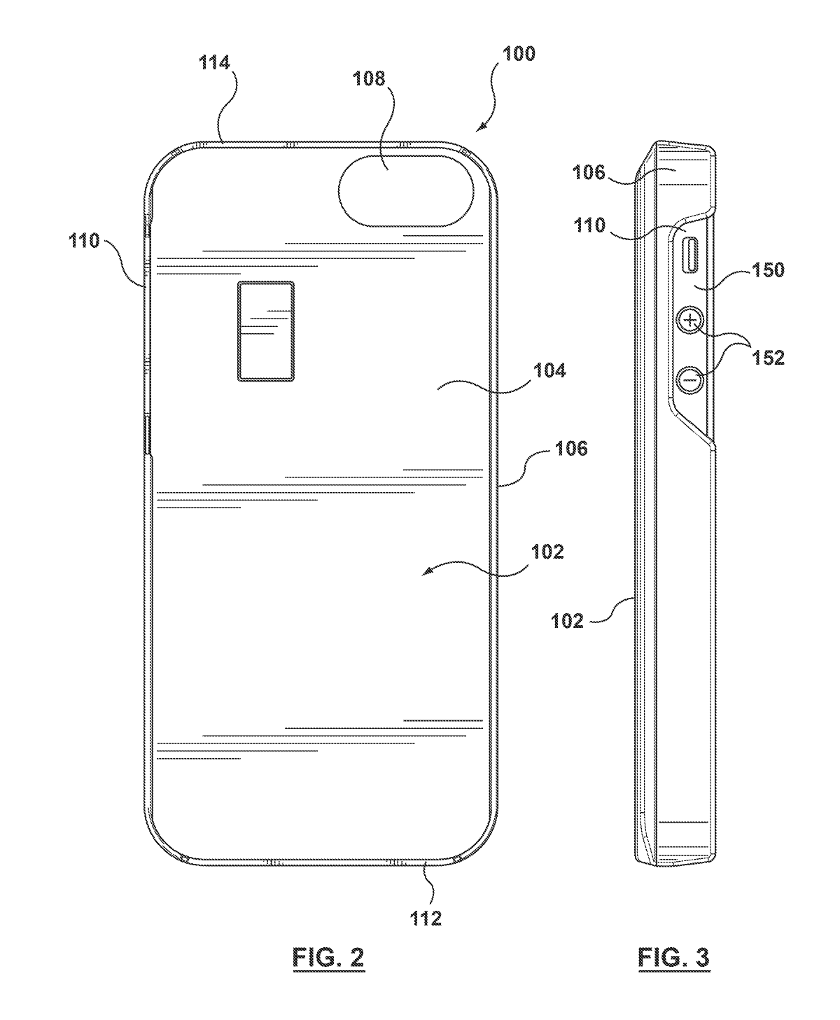

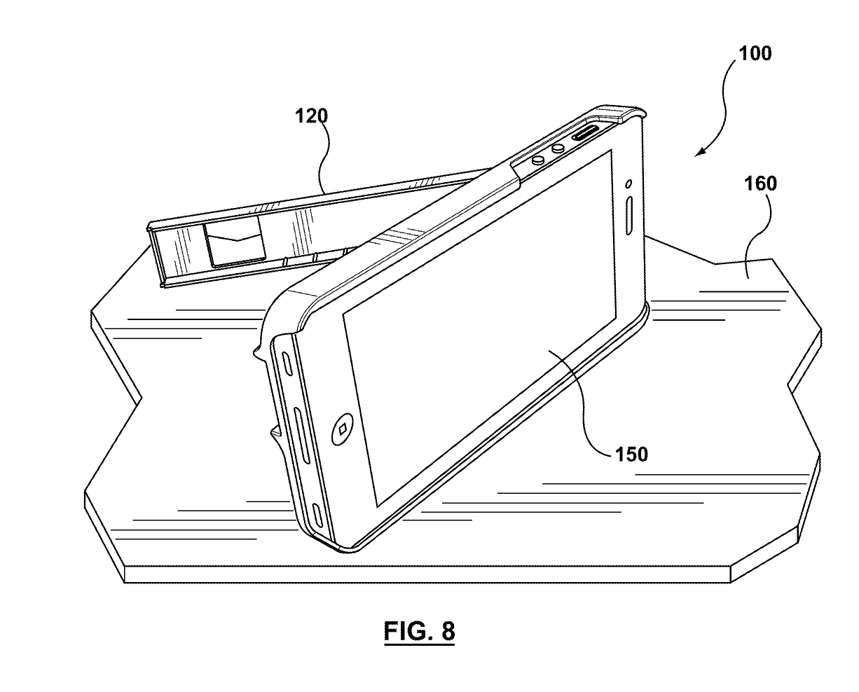

Embodiments hereof relate to an electronic device case 100 for protecting, viewing and operating an electronic device 150. Case 100 may be formed from a relatively hard or rigid material that operates to protect the electronic device from breakage or damage, but is also flexible enough to conform to the shape of electronic device. In particular, material generally used for mobile phone or tablet cases may be used, or other suitable materials. In the embodiment depicted in FIGS. 1-9, case 100 is sized and shaped to hold a mobile telephone or smartphone therein, such as, but not limited to, an iPhone® available from Apple®, a Galaxy® available from Samsung®, a Blackberry®, and other similar devices. Case 100 includes a panel 102 including a back surface 103 and a front surface 104. Side panels or edges 106 extend away from front surface 104 and are configured to extend around sides of electronic device 150 to attach case 100 to electronic device 150. Panel 102 may include apertures or openings 108 located for access to parts of electronic device. For example, and not by way of limitation, opening 108 may be for a camera lens of the electronic device 150. Similarly, edges 106 may include apertures, openings, or gaps 110, 112, and 114, which are located for access to parts of electronic device 150. For example, and not by way of limitation, gaps 110, 112, 114 may be provided for access to buttons, earphone plugs, and charging plugs of the electronic device 150. Accordingly, the quantity, size, and location of such openings or gaps may be varied depending on the particular electronic device for which the case 100 is designed.

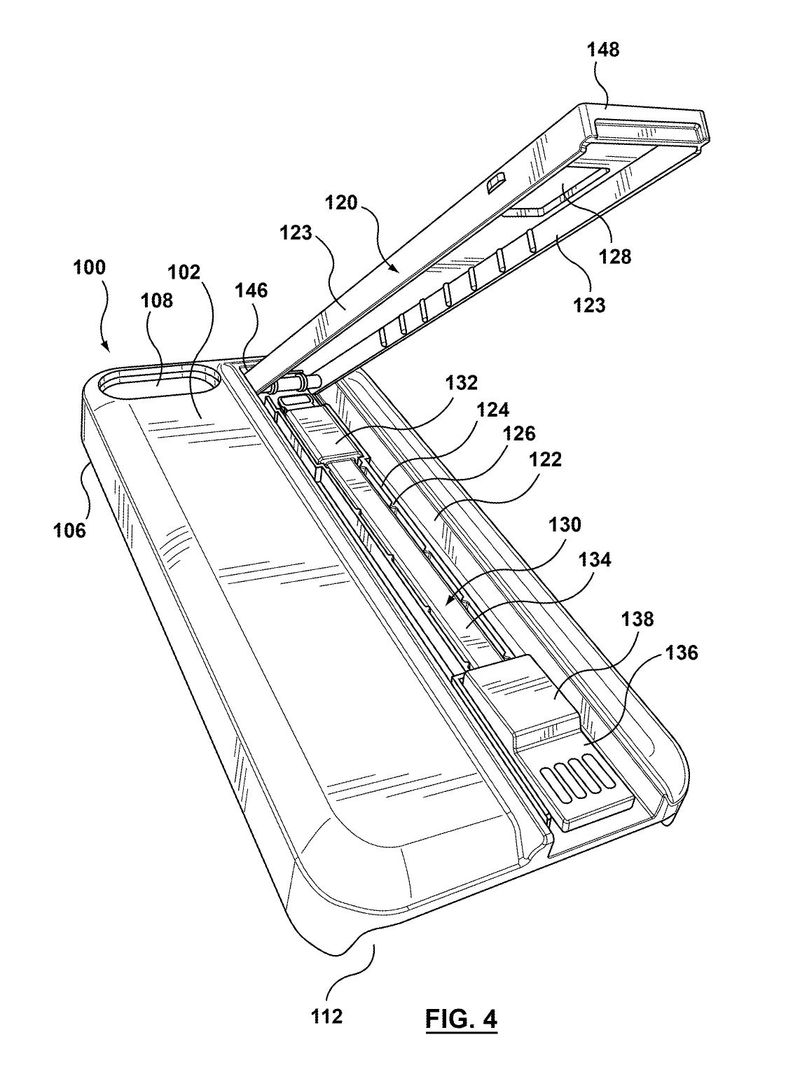

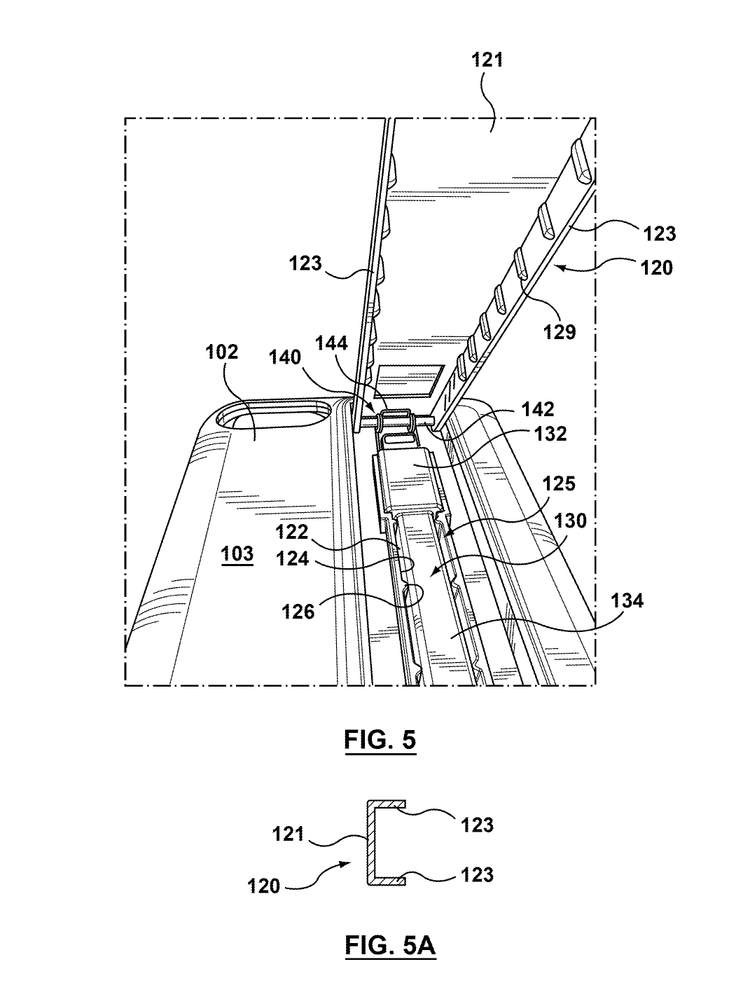

FIG. 1 shows a view of back surface 103 of case 100. Case 100 includes a kickstand 120 that is shown in a closed configuration in FIG. 1. FIGS. 4 and 5 show kickstand 120 in an open or deployed configuration. In the embodiment shown, kickstand 120 is generally C-shaped in cross-section, and includes a back wall 121 and two sidewalls or arms 123 extending from the back panel, as shown in FIG. 5A. As can be seen in FIGS. 1 and 4-5, kickstand 120 in the closed configuration sits in a recess 122 in back surface 103 of panel 102. In particular, arms 123 extend into recess 122 such that back panel 121 of kickstand 120 is flush with back surface 103 of panel 102, as shown in FIG. 1.

Kickstand 120 is connected to panel 102 using a hinge connection 140, as shown in FIG. 5, which allows a first end 146 of kickstand 120 to rotate about pin 142 of hinge connection 140. As first end 146 rotates around pin 142, second end 148 of kickstand 120 moves away from or toward panel 102. Hinge connection 140 may also include a spring 144 to bias kickstand 120 in a particular direction, i.e., open or closed, as known to those skilled in the art. Hinge connection 140 is shown as a pin and spring connection, but other hinge connections or connections which permit kickstand 120 to open and close may also be used.

Recess 122 also provides a storage area 125 for a charge or data cable 130. In the embodiment shown in FIGS. 4-5 recess includes walls 124 which form storage area 125 which is sized and shaped to accommodate charge or data cable 130 therein. In the embodiment shown, storage area 125 is larger than storage or data cable 130 and walls 124 include extensions or bumps 126 which extend into storage area to create a friction fit between walls 124 and charge or data cable 130. Thus, charge or data cable 130 remains seated in storage area 125 even when kickstand 120 is in the open configuration. In order to remove charge or data cable 130 from storage area 125, a user may pull charge or data cable 130 out of storage area 125 with sufficient force to overcome the friction force between walls 124 and charge or data cable 130. Although the particular embodiment shown utilizes extensions or bumps 126, other ways to secure charge or data cable 130 within storage area 125 may be utilized, such as, but not limited to, a friction fit without extensions or bumps 126, a snap fit, a retention element, or other ways to secure charge or data cable within storage area 125. Further, arms 123 of kickstand may include extends or bumps 129 extend inwardly to provide a friction fit with walls 124 defining storage area 125, as shown in FIG. 5.

As seen in FIGS. 4, 8 and 9, charge or data cable 130 may include a first male connector 132 at a first end thereof, a second male connector 136 at a second end thereof, and a cable 134 therebetween. In the embodiment shown, first male connector 132 is configured to fit into the female connector or port for charging an iPhone® 5. In other embodiments of case 100 for use with other devices, first male connector 132 may be a connector configured to fit into the corresponding charging port of the device for which case 100 is configured. Also in the embodiment shown, second male connector 136 is a USB connector configured to engage a USB port. In other embodiments, second male connector 136 may be other types of connectors for use with electronic devices. Cable 134 may be any type of cable suitable for use as a charge or data cable for an electronic device.

In an embodiment, kickstand 120 may include an opening 128 through wall 121 to accommodate a thickened portion 138 of charge or data cable 130, as shown at least in FIGS. 1 and 4. Thickened portion 138 may also include a symbol or icon 139 that shows through opening 128 when kickstand 120 is closed to indicate that the charge or data cable 130 is located within kickstand 120, as shown in FIG. 1.

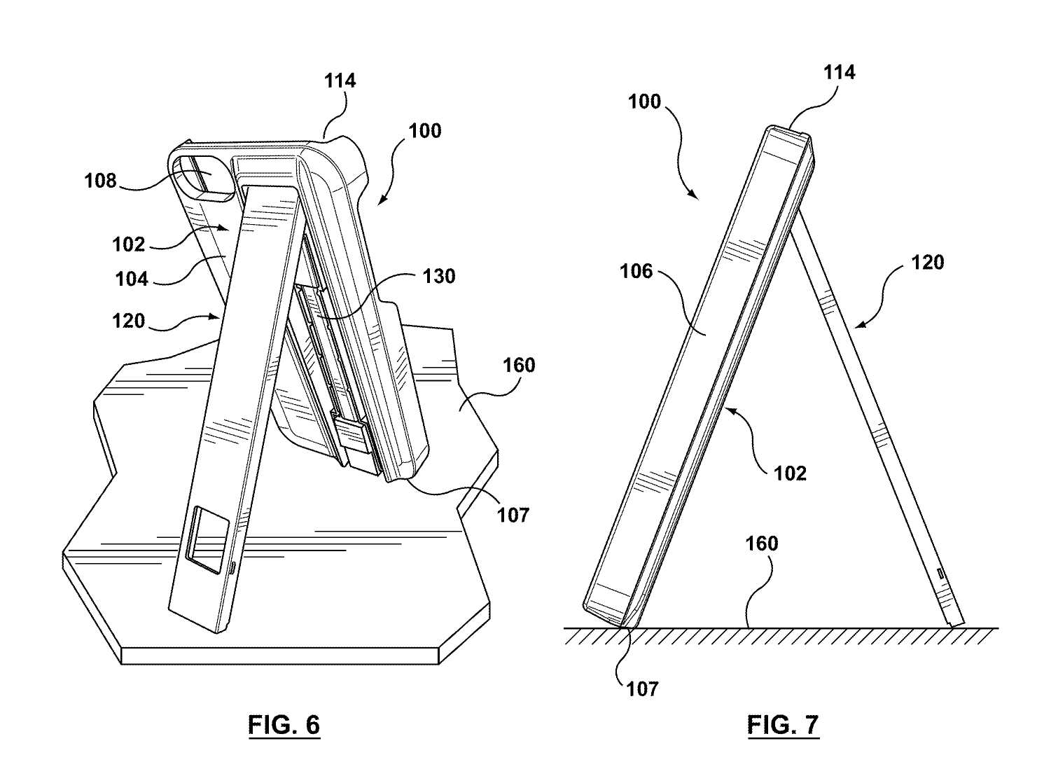

FIGS. 6-9 show case 100 in use with a smartphone as electronic device 150 disposed therein. In FIGS. 6 and 7, charge or data cable 130 is disposed in storage area 125 and kickstand 120 is opened. First end 146 of kickstand 120 is hingedly connected to panel 102, as described above. Second end 148 of kickstand 120 and bottom edge 107 of case 100 rest against a surface 160 such that electronic device 150 is in a portrait viewing mode. As shown in FIGS. 6 and 7, charge or data cable 130 is disposed in storage area 125 of recess 122 while the user views electronic device 150 in the portrait mode. Similarly, with kickstand 120 opened, case 100 may be rotated 90 degrees such that second end 148 of kickstand 120 and a side edge 106 of case 100 rest against surface 160 such that electronic device 150 may be viewed in landscape mode. Charge or date cable 130 may remain in storage area 125 of recess 122 during use by the user. Further, although the embodiments have been described with charge or data cable 130 disposed in storage area 125 of recess 122 during use, charge or data cable 130 may also be removed from storage area 125 while kickstand 120 is opened for use.

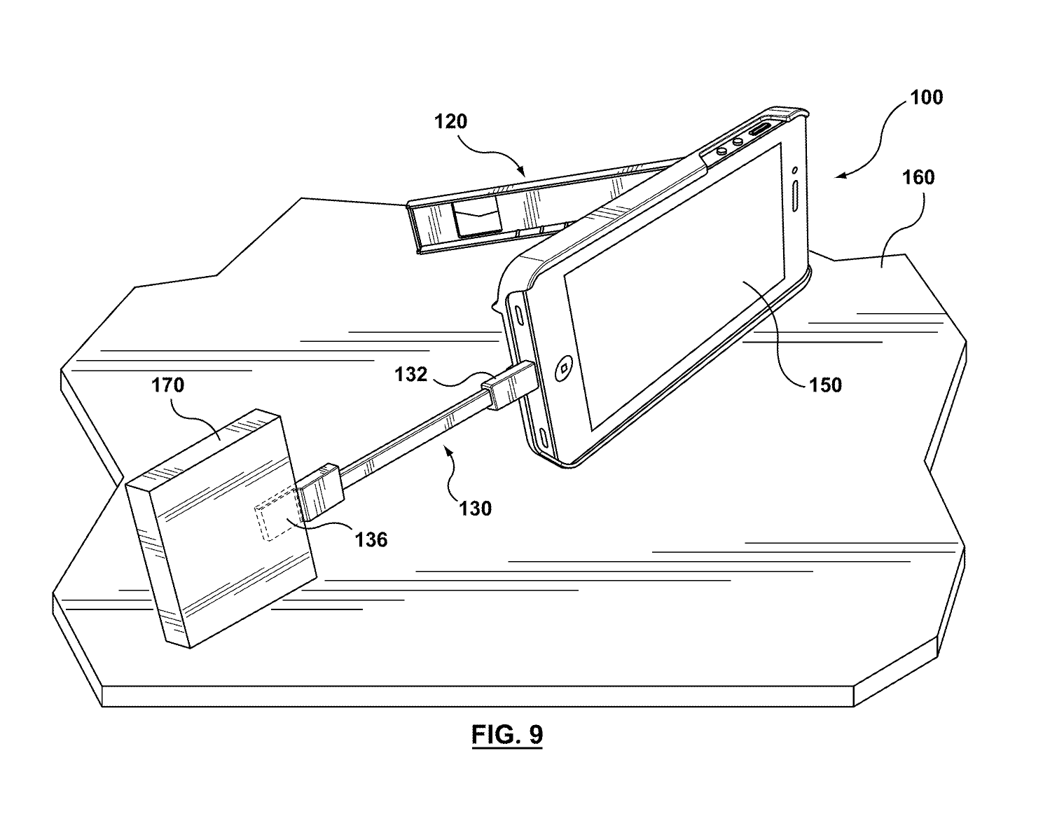

Further, the embodiment shown allows a user to utilize kickstand 120 while charging electronic device 150 with charge or data cable 130 or otherwise using charge or data cable 130 in connection with electronic device 150. For example, as shown in FIG. 9, charge or data cable 130 is removed from storage area 125. First male connector 132 of charge or data cable 130 is connected to the charging port of electronic device 150. Second male connector 136 of charge or data cable 130 is connected to a charging or data device 170. For example, and not by way of limitation, charging or data device 170 may be a personal computer, a laptop, or may be an adaptor which adapts second male connector 136 to be plugged into a wall socket, or other devices suitable for use for charging or transferring data to or from electronic device 150. In the embodiment shown, the charging port of electronic device 150 is disposed at a bottom edge of electronic device 150. Accordingly, the landscape viewing mode shown in FIG. 9 is most convenient when kickstand 120 is open and charge or data cable 130 is connected to the charging port of electronic device 150. However, with different devices, the charging port may be located in other locations such that portrait viewing is preferable, or both landscape and portrait views are convenient. Further, kickstand 120 may be oriented in the opposite direction such that the charging port of electronic device 150 may be oriented on the opposite edge of surface 160 when electronic device 150 is in the portrait mode. The ability of many electronic devices to operate in either orientation would thus permit portrait and landscape viewing with kickstand 120 open and charge or data cable 130 connected to the charging port of electronic device 150.

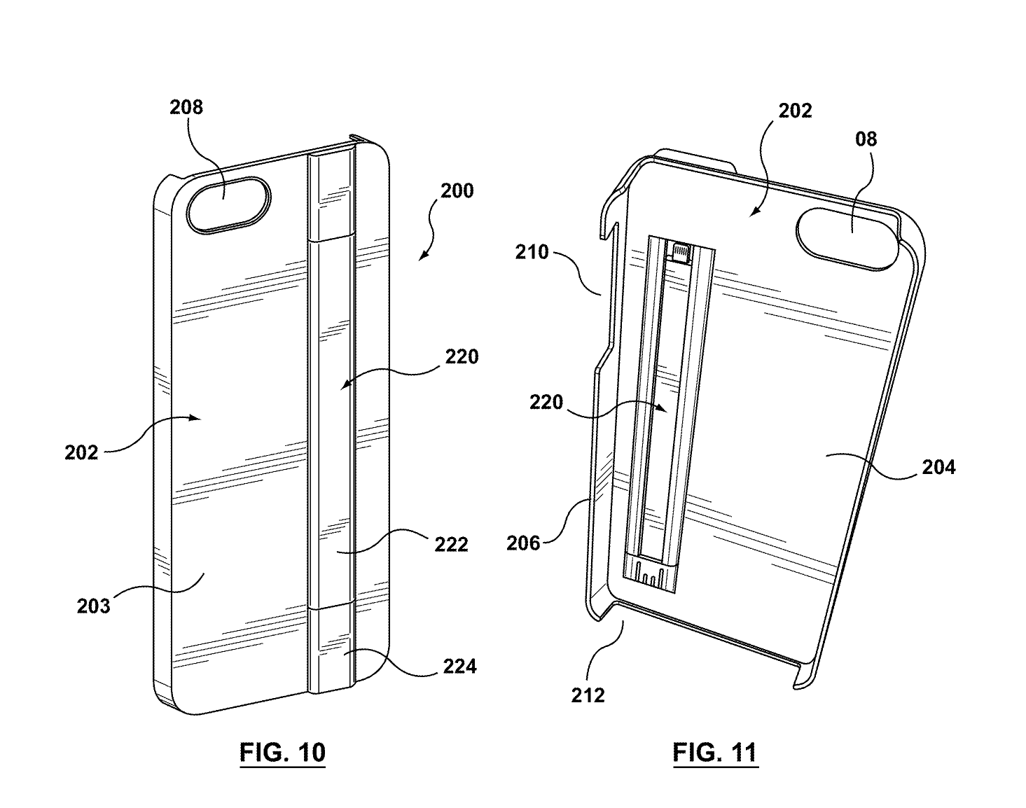

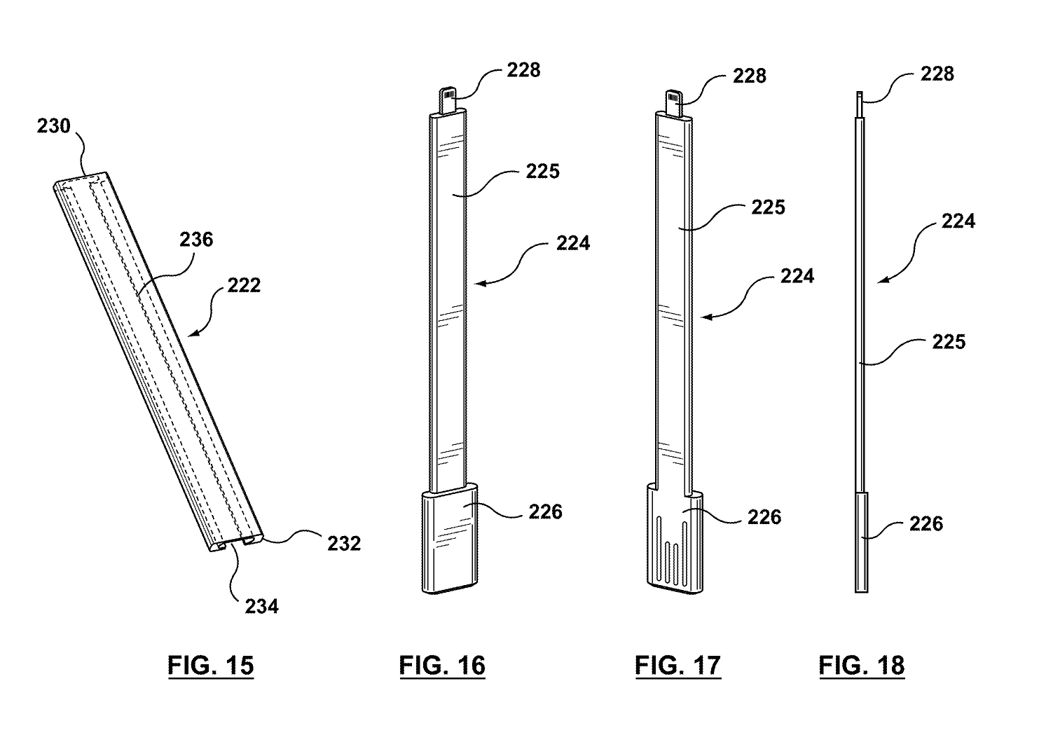

FIGS. 10-21 show another embodiment of an electronic device case 200 for protecting, viewing and operating an electronic device 250. Case 200 may be formed from a relatively hard or rigid material that operates to protect the electronic device from breakage or damage, but is also flexible enough to conform to the shape of electronic device 250. In particular, material generally used for mobile phone or tablet cases may be used, or other suitable materials. In the embodiment depicted in FIGS. 10-21, case 200 is sized and shaped to hold a mobile telephone or smartphone therein, such as, but not limited to, an iPhone® available from Apple®, a Galaxy® available from Samsung®, a Blackberry®, and other similar devices. Case 200 includes a panel 202 including a back surface 203 and a front surface 204. Side panels or edges 206 extend away from front surface 204 and are configured to extend around sides of electronic device 250 to attach case 200 to electronic device 250. Panel 202 may include apertures or openings 208 located for access to parts of electronic device. For example, and not by way of limitation, opening 208 may be for a camera lens of the electronic device 250. Similarly, edges 206 may include apertures, openings, or gaps 210, 212, and 214, which are located for access to parts of electronic device 250. For example, and not by way of limitation, gaps 210, 212, 214 in edges 206 may be provided for access to buttons, earphone plugs, and charging plugs of the electronic device 250. Accordingly, the quantity, size, and location of such openings or gaps may be varied depending on the particular electronic device for which the case 200 is designed.

FIG. 10 shows a view of back surface 203 of case 200. Case 200 includes a kickstand 220 that is shown in a closed configuration in FIG. 10. Similarly, FIG. 11 shows a view of case from front surface 204 with kickstand 220 in a closed configuration, without electronic device 250 disposed in case 200. Kickstand 220 in the closed configuration is disposed in an opening 209 of panel 202 of case 200. In other embodiments, kickstand 220 may instead by disposed in a recess in panel 202 in the closed configuration.

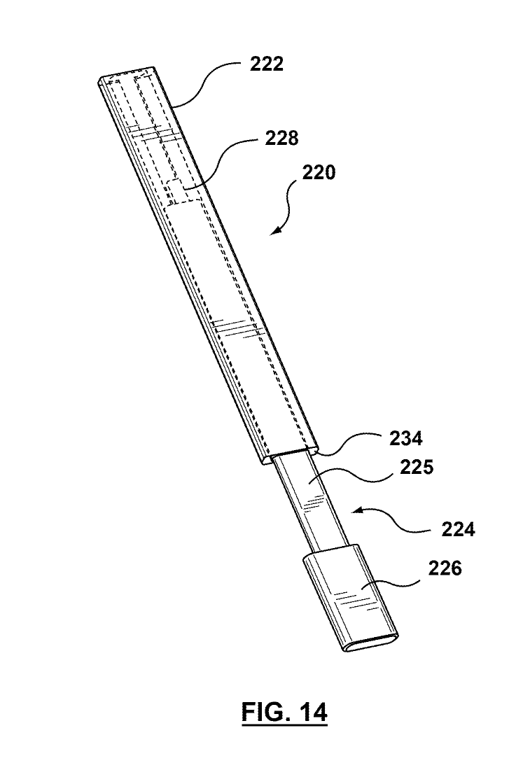

FIGS. 14-18 show that kickstand 220 is formed from a support tube 222 and a charge or data cable 224 which may be disposed in support tube 222 for storage or removed from support tube for use, as explained in more detail below. In particular, support tube 222 includes a first end 230 hingedly connected to panel 202 and a second end 232. Second end 232 includes an opening 234 communicating with a bore 236 disposed through support tube 222. First end 230 is closed such that bore 236 does not extend all the way through support tube 222. However, in some embodiments, bore 236 may extend entirely through support tube 222. Bore 236 is sized and shaped to house charge or data cable 224. In the drawings, the side of support tube 222 facing panel 202 is shown with a slot along the length thereof. However, support tube 222 does not need to have such a slot. Instead, support tube 222 can be solid around its exterior, with bore 236 extending therethrough.

Charge or data cable 224 may be similar to charge or data cable 130 described above. In particular, charge or data cable 224 include a first male connector 228 at a first end thereof, a second male connector 226 at a second end thereof, and a cable 225 disposed between the first and second male connectors 228, 226. First male connector 228 is configured to fit into the female connector or port for charging the electronic device 250 for which case 200 is configured. Second male connector 226 may be a USB connector configured to engage a USB port. In other embodiments, second male connector 226 may be other types of connectors for use with electronic devices. Cable 225 may be any type of cable suitable for use as a charge or data cable for an electronic device.

As noted above, charge or data cable 224 is sized and shaped to fit into bore 236 of support tube 222. In the embodiment shown, second male connector 226 disposed at the second end of charge or data cable 224 does not enter bore 236. Instead, second male connector 226 abuts second end 232 of support tube 222, as shown in FIGS. 10-13. Charge or data cable 224 may be held in support tube 222 by friction, a snap-fit, or other ways to hold charge or data cable 224 in support tube 224. For example, and not by way of limitation (and not shown), an extension of support tube 222 may extend into bore 236 and catch and extension extending radially outwardly from charge or data cable 224 adjacent second male connector 236. Other ways to secure charge or data cable 224 within bore 236 of support tube may be utilized, as would be understood by those skilled in the art.

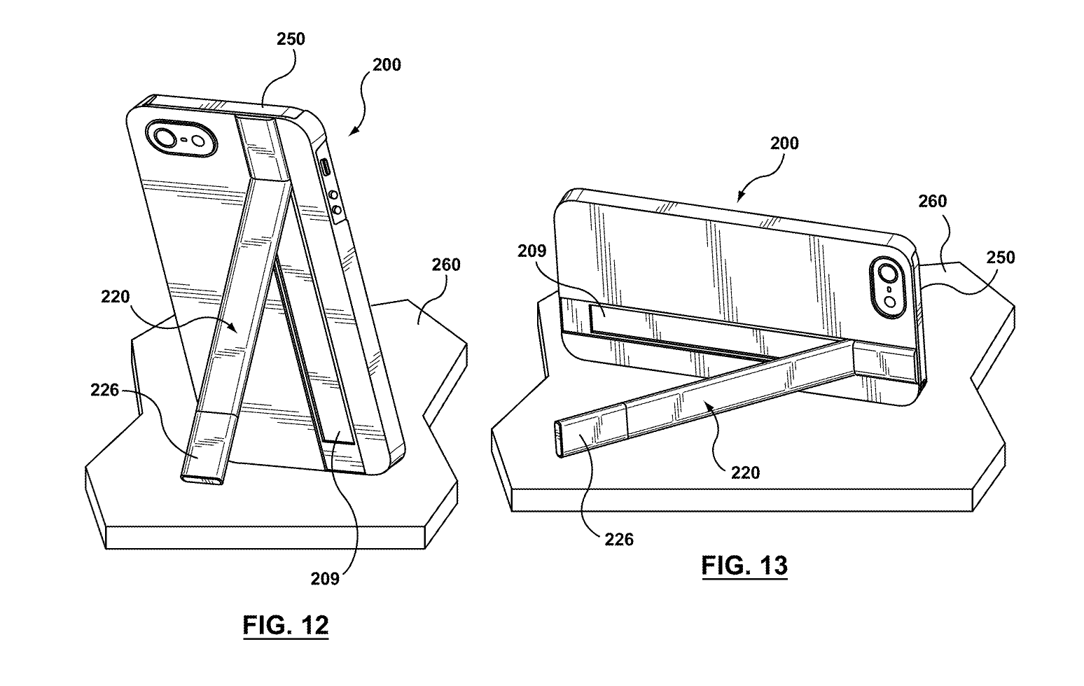

With charge or data cable 224 disposed within support tube 222 for storage, kickstand 220 may be opened by rotating first end 230 of support tube 22 around the hinged connection (not shown) to panel 202, as described above. As shown in FIGS. 12 and 13, with kickstand 220 in the open configuration, case 200 may be oriented on a surface 260 for portrait (FIG. 12) or landscape (FIG. 13) viewing. In particular, in portrait viewing (FIG. 12), a bottom edge of case 200 and second male connector 226 of charge or data cable 224 disposed in support tube 222 rest against surface 260 to support case 200 in a portrait viewing configuration. In landscape viewing (FIG. 13), a side edge of case 200 and a corner or side edge of second male connector 226 rest against surface 260 to support case 200 in a landscape viewing configuration.

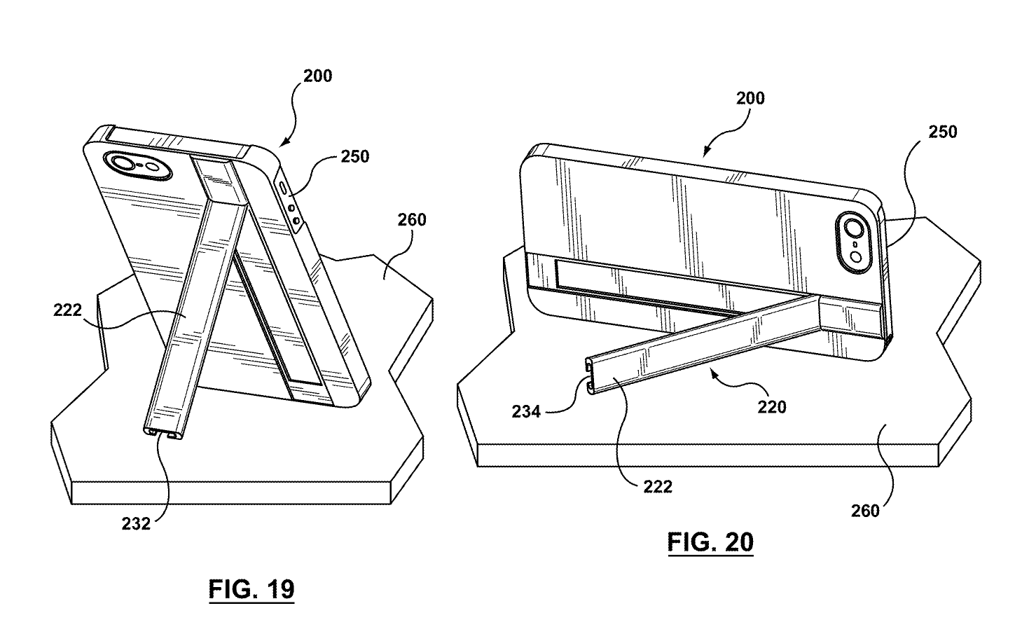

Similarly, support tube 222 may be used to support case 200 and electronic device disposed therein in portrait and landscape viewing configurations with charge or data cable 224 removed from support tube 222. In particular, as shown in FIG. 19, with kickstand support tube 222 of kickstand 220 in the open configuration, case 200 may be oriented on a surface 260 for portrait (FIG. 19) or landscape (FIG. 20) viewing. In particular, in portrait viewing (FIG. 19), a bottom edge of case 200 and second end 232 of support tube rest against surface 260 to support case 200 in a portrait viewing configuration. In landscape viewing (FIG. 20), a side edge of case 200 and a corner or side edge of second end 232 of support tube 222 rest against surface 260 to support case 200 in a landscape viewing configuration.

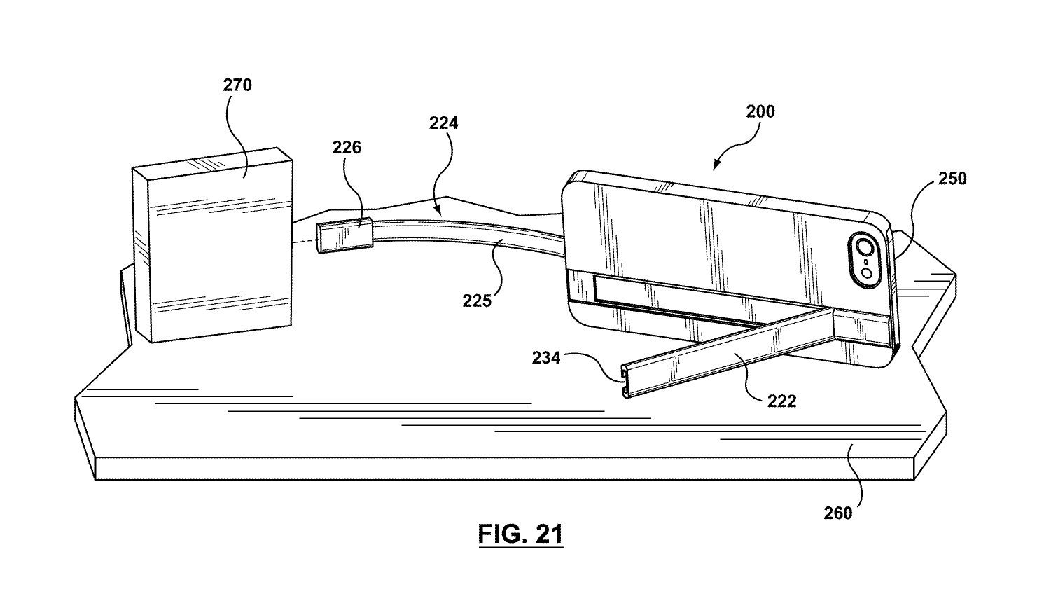

The embodiment shown allows a user to utilize kickstand support tube 222 as a kickstand while charging or transferring data to or from electronic device 250 with charge or data cable 224, or otherwise using charge or data cable 224 in connection with electronic device 224. For example, as shown in FIG. 21, charge or data cable 224 is removed from support tube 222. First male connector 228 of charge or data cable 224 is connected to the charging port of electronic device 250. Second male connector 226 of charge or data cable 224 is connected to a charging or data device 270. For example, and not by way of limitation, charging or data device 270 may be a personal computer, a laptop, or may be an adaptor which adapts second male connector 226 to be plugged into a wall socket, or other devices suitable for use for charging or transferring data to or from electronic device 250. In the embodiment shown, the charging port of electronic device 250 is disposed at a bottom edge of electronic device 250. Accordingly, the landscape viewing mode shown in FIG. 21 is most convenient when support tube 222 is open and charge or data cable 224 is connected to the charging port of electronic device 250. However, with different devices, the charging port may be located in other locations such that portrait viewing is preferable, or both landscape and portrait views are convenient. Further, support tube 222 may be oriented in the opposite direction such that the charging port of electronic device 250 may be oriented spaced apart from surface 260 when electronic device 250 is in the portrait mode. The ability of many electronic devices to operate in either orientation would thus permit portrait and landscape viewing with support tube 222 open and charge or data cable 224 connected to the charging port of electronic device 250.

Further, although in the embodiment shown in FIGS. 10-21 second male connector 226 of charge or data cable 224 is disposed outside of bore 236 of support tube 222, in other embodiments the charge or data cable may be disposed entirely in bore 236 with an access opening to allow a user to begin removal of charge or data cable from bore 235. In such an embodiment, the length of the kickstand 220 with charge or data cable “on board” or “off board” does not change.

While various embodiments according to the present invention have been described above, it should be understood that they have been presented by way of illustration and example only, and not limitation. Further, each of the embodiments and parts described with respect to such embodiments may be used with each of the other embodiments. For example, and not by way of limitation, the adjustable angle described with respect to the removably attached strap 240 may be used in the embodiment of FIGS. 1-13. It will be apparent to persons skilled in the relevant art that various changes in form and detail can be made therein without departing from the spirit and scope of the invention. Thus, the breadth and scope of the present invention should not be limited by any of the above-described exemplary embodiments, but should be defined only in accordance with the appended claims and their equivalents. It will also be understood that each feature of each embodiment discussed herein, and of each reference cited herein, can be used in combination with the features of any other embodiment. All patents and publications discussed herein are incorporated by reference herein in their entirety.

What is claimed is:

1. An electronic device case comprising:
a panel including a front surface, a back surface, and a recess;
a kickstand with a first end hingedly connected to the panel such that the kickstand in a closed configuration is at least partially disposed in the recess of the panel and in an open configuration a second end of the kickstand is spaced from the panel; and
a storage area disposed in the recess, wherein the storage area is configured to hold a charge or data cable for the electronic device, wherein the storage area is configured such that the charge or data cable may be disposed therein with kickstand in the closed configuration and the open configuration.

2. The electronic device case of claim 1, wherein the storage area is defined by storage area walls disposed within the recess, wherein the walls are sized and shaped to receive the charge or data cable.

3. The electronic device case of claim 2, wherein the kickstand is generally C-shaped in cross-section such that the kickstand includes a back wall and a pair of side walls extending from the back wall, and wherein in the closed configuration, each of the pair of side walls extends into the recess outside a respective one of the storage area walls and the back wall is generally parallel to the panel.

4. The electronic device case of claim 3, wherein at least one of the side walls of the kickstand includes bumps for frictional engagement of the respective storage area wall.

5. The electronic device case of claim 1, wherein the kickstand is generally C-shaped in cross-section such that the kickstand includes a back wall and a pair of side walls, and wherein in the closed configuration, the pair of side walls extend into the recess and the back wall is generally parallel to the panel.

6. The electronic device case of claim 1, wherein the hinge connection is biased to close the kickstand.

7. An electronic device case comprising:
a panel including a front surface and a back surface; and
a kickstand including a support tube with a first end hingedly connected to the panel such that the support tube in a closed configuration is at least partially disposed in an opening or recess of the panel and in an open configuration a second end of the support tube is spaced from the panel,
wherein the support tube includes a bore disposed longitudinally, wherein the bore is configured to hold a charge or data cable for the electronic device.

8. The electronic device case of claim 7, wherein the kickstand is defined by the support tube and the charge or data cable when the charge or data cable is disposed in the bore and by the support tube when the charge or data cable is removed from the support tube.

9. The electronic device case of claim 7, wherein the charge or data cable is disposed entirely within the bore when the charge or data cable is disposed in the support tube.
